(19) United States
(12) Patent Application Publication
(10) Pub. No.: US 2013/0203203 A1
(43) Pub. Date: Aug. 8, 2013

(54) MANUFACTURING METHOD FOR FLEXIBLE SOLAR CELL MODULES

(71) Applicants: Kiyomi Uenomachi, Osaka (JP); Masahiro Asuka, Osaka (JP); Hiroshi Hiraike, Osaka (JP); Takahiro Nomura, Osaka (JP); Jiamo Guo, Osaka (JP); Takahiko Sawada, Osaka (JP)

(72) Inventors: Kiyomi Uenomachi, Osaka (JP); Masahiro Asuka, Osaka (JP); Hiroshi Hiraike, Osaka (JP); Takahiro Nomura, Osaka (JP); Jiamo Guo, Osaka (JP); Takahiko Sawada, Osaka (JP)

(21) Appl. No.: 13/821,605

(22) PCT Filed: Sep. 20, 2011
(86) PCT No.: PCT/JP2011/071378

§ 371 Date: Apr. 24, 2013

(30) Foreign Application Priority Data
Sep. 30, 2010 (JP) 2010-223103
Mar. 18, 2011 (JP) 2011-061597

(51) Int. Cl. H01L 31/0203

(52) U.S. Cl. CPC H01L 31/0203
USPC 438/64

(57) ABSTRACT

An object of the present invention is to provide a method for producing a flexible solar cell module which makes it possible to suitably produce flexible solar cell modules in which a solar cell element and a solar cell encapsulant sheet are well adhered to each other by encapsulating a solar cell by roll-to-roll processing in a continuous manner without the need to perform a crosslinking process and without causing wrinkles and curls. The present invention is a method for producing a flexible solar cell module, including thermocompression bonding of a solar cell encapsulant sheet to at least a light-receiving surface of a solar cell element that includes a flexible substrate and a photoelectric conversion layer on the flexible substrate by pressing the solar cell encapsulant sheet and the solar cell element together between a pair of heating rolls, the solar cell encapsulant sheet including a fluoropolymer sheet and an adhesive layer on the fluoropolymer sheet, the adhesive layer including a silane-modified polyolefin resin.

### TECHNICAL FIELD

The present invention relates to a method for producing a flexible solar cell module which makes it possible to encapsulate a solar cell element in a continuous manner without the need to perform a crosslinking process and highly efficiently produce flexible solar cell modules in which a solar cell element and a solar cell encapsulant sheet are well adhered to each other without causing wrinkles and curls.

### BACKGROUND ART

Solar cell modules known so far are: rigid solar cell modules that include a glass substrate; and flexible solar cell modules that include a thin film substrate of stainless steel or a substrate made of a heat resistant polymer material such as polyimide or polyester. In recent years, flexible solar cell modules have been attracting attention because they are easy to transport and install due to their thin and lightweight designs, and have high impact resistance.

A flexible solar cell module is a laminate of a flexible solar cell element and solar cell encapsulant sheets encapsulating the upper and lower surfaces of the flexible solar cell element. The flexible solar cell element is a laminate created by stacking, on a flexible substrate, a thin photoelectric conversion layer made of a silicon semiconductor, a compound semiconductor, or the like which generates a current when exposed to light.

The solar cell encapsulant sheets serve to mitigate impacts from the exterior and protect the solar cell element from corrosion, and consist of a transparent sheet and an adhesive layer on the transparent sheet. The adhesive layers, which are designed to encapsulate the solar cell element, have been made using ethylene-vinyl acetate (EVA) resins (for example, Patent Literature 1).

The use of EVA resins, however, has some problems such as an extended production time and generation of an acid because it requires a crosslinking process. In view of these problems, some attempts have been made to form an adhesive layer of a solar cell encapsulant sheet using a non-EVA resin such as a silane-modified olefin resin (for example, Patent Literature 2).

Flexible solar cell modules have been conventionally produced by a method involving cutting a flexible solar cell element and solar cell encapsulant sheets into desired shapes, stacking the cut pieces, and bonding them together into an integrated laminate in a static state by vacuum laminating. Such vacuum laminating methods take a long time to finish bonding, and therefore are disadvantageously less efficient in producing solar cell modules.

One of methods for producing a flexible solar cell module under study is roll-to-roll processing that is advantageous for mass production (for example, Patent Literature 3).

The roll-to-roll processing is a technique to produce a flexible solar cell module in a continuous manner, and uses a roll of a solar cell encapsulant film sheet. The solar cell encapsulant sheet is unrolled, and subjected to thermocompression bonding in which the solar cell encapsulant sheet is pressed together with a solar cell element between a pair of rolls to encapsulate the solar cell element.

The roll-to-roll processing is expected to enable continuous and remarkably efficient production of flexible solar cell modules.

However, the roll-to-roll processing, when used to produce a flexible solar cell module by encapsulating a flexible solar cell element with a conventional solar cell encapsulant sheet, causes some problems that strikingly reduce the production efficiency, such as the need to perform a crosslinking process and occurrence of wrinkles and curls upon thermocompression bonding of the flexible solar cell element and the solar cell encapsulant sheet between rolls, and other problems such as insufficient adhesion between the flexible solar cell element and the solar cell encapsulant sheet.

In this context, there has been a demand for a method that maintains the high production efficiency of the roll-to-roll processing enough, prevents wrinkles and curls, and allows a flexible solar cell element to be well encapsulated in a continuous manner.

### CITATION LIST

### Patent Literature

Patent Literature 1: Japanese Kokai Publication No. Hei-07-297439 (JP-A H07-297439)
Patent Literature 2: Japanese Kokai Publication No. 2004-214641 (JP-A 2004-214641)
Patent Literature 3: Japanese Kokai Publication No. 2000-294815 (JP-A 2000-294815)

### SUMMARY OF INVENTION

### Technical Problem

In view of the above-mentioned situation, the present invention provides a method for producing a flexible solar cell module which makes it possible to encapsulate a solar cell element in a continuous manner without the need to perform a crosslinking process and highly efficiently produce flexible solar cell modules in which a solar cell element and a solar cell encapsulant sheet are well adhered to each other without causing wrinkles and curls.

### Solution to Problem

The present invention is a method for producing a flexible solar cell module, including thermocompression bonding of a solar cell encapsulant sheet to at least a light-receiving surface of a solar cell element that includes a flexible substrate and a photoelectric conversion layer on the flexible substrate by pressing the solar cell encapsulant sheet and the solar cell element together between a pair of heating rolls, the solar cell encapsulant sheet including a fluoropolymer sheet and an adhesive layer on the fluoropolymer sheet, the adhesive layer including a silane-modified polyolefin resin.

The following description is offered to illustrate the present invention in detail.

The present invention relates to production of a flexible solar cell module in which a solar cell element and a solar cell encapsulant sheet that includes an adhesive layer containing specific components and a fluoropolymer sheet are well adhered to each other by encapsulating the solar cell element with the solar cell encapsulant sheet in a continuous manner by roll-to-roll processing without causing wrinkles and curls.

The present inventors found that in the case that a solar cell encapsulant sheet that includes a fluoropolymer sheet and an adhesive layer containing a silane-modified polyolefin resin (a polyolefin resin grafted with an ethylenic unsaturated silane compound) on the fluoropolymer sheet is used to encapsulate a solar cell element, the encapsulation can be accomplished in a comparatively short time by thermocompression bonding at a comparatively low temperature without the need to perform a crosslinking process, and in a continuous manner by roll-to-roll processing, thereby completing the present invention.

The method for producing a flexible solar cell module of the present invention includes thermocompression bonding of a solar cell encapsulant sheet to at least a light-receiving surface of a solar cell element that includes a flexible substrate and a photoelectric conversion layer on the substrate by pressing them between a pair of heating rolls.

The solar cell encapsulant sheet includes an adhesive layer containing a silane-modified polyolefin resin on a fluoropolymer sheet.

The present invention makes use of a solar cell encapsulant sheet that includes such an adhesive layer containing a specific resin to suitably produce flexible solar cell modules by roll-to-roll processing.

The silane-modified polyolefin resin is a resin prepared by grafting an ethylenic unsaturated silane compound to a polyolefin in the presence of a radical generator.

Since a polyolefin grafted with an ethylenic unsaturated silane compound is used, the resin in the adhesive layer is a polyolefin having an alkoxysilyl group. This allows the adhesive layer to exhibit better adhesion to the solar cell element, and additionally, because of crosslinks between the silane compound molecules, the durability of the solar cell encapsulant sheet is improved.

The polyolefin preferably has a maximum peak temperature (Tm) of not lower than 70° C. and lower than 125° C. as determined from an endothermic curve obtained by differential scanning calorimetry. If the maximum peak temperature (Tm) determined from an endothermic curve is lower than 70° C., the solar cell encapsulant sheet may be less heat resistant and may not be suited for outdoor use. If the maximum peak temperature is 125° C. or higher, the solar cell encapsulant sheet may require higher-temperature lamination, leading to lower production efficiency of flexible solar cell modules.

In the present invention, endothermic curves of synthetic resins are obtained by differential scanning calorimetry in accordance with the method specified in JIS K7121.

Ethylene-α-olefin copolymers may be mentioned as preferred examples of polyolefins usable in the present invention which have a maximum peak temperature (Tm) of not lower than 70° C. and lower than 125° C. as determined from an endothermic curve obtained by differential scanning calorimetry.

Examples of α-olefins include propylene, butene-1, hexene-1,4-methyl-pentene-1, octene-1, vinyl acetate, acrylic acid, methacrylic acid, acrylic acid esters, and methacrylic acid esters. Any of these may be used alone, or a combination of two or more of these may be used.

Regarding the ethylene-to-α-olefin copolymerization ratio of these ethylene-α-olefin copolymers, the ratio of the α-olefin in these copolymers is preferably not less than 5% by weight and less than 40% by weight. Disadvantageously, an ethylene-α-olefin copolymer having an α-olefin ratio of less than 5% by weight may have a melting point of 125° C. or higher, and an ethylene-α-olefin copolymer having an α-olefin ratio of 40% by weight or more may have a melting point of lower than 70° C.

Examples of the ethylenic unsaturated silane compound to be grafted to the polyolefin include vinyltrimethoxysilane, vinyltriethoxysilane, vinyltri(2-methoxyethoxy)silane, vinyltripropoxysilane, vinyltriisopropoxysilane, vinyltributoxysilane, vinyltripentyloxysilane, vinyltriphenoxysilane, vinyltribenzyloxysilane, vinyltrimethylenedioxysilane, vinyltriethylenedioxysilane, vinylpropionyloxysilane, vinyltriacetoxysilane, and vinyltricarboxysilane. Any of these may be used alone, or a combination of two or more of these may be used.

The amount of the ethylenic unsaturated silane compound to be grafted to the polyolefin is preferably not less than 0.1 parts by weight and less than 10 parts by weight relative to 100 parts by weight of the polyolefin. If the amount of the ethylenic unsaturated silane compound is less than 0.1 parts by weight, the adhesion of the solar cell encapsulant sheet to the solar cell element may be week. If the amount is 10 parts by weight or more, the density of crosslinks between the silane compound molecules may be so high that gelation may occur in the process of forming the solar cell encapsulant sheet. Consequently, holes may be formed, or the solar cell encapsulant sheet may be torn.

The grafting may be carried out by any methods without limitation, and conventional methods can be used. Examples thereof include a method including adding a radical generator to the polyolefin and the ethylenic unsaturated silane compound, and kneading them at a temperature of not lower than the one-hour half-life temperature of the radical generator. The kneading can be carried out by using a single or twin screw extruder, a kneader, a Bunbury mixer, or the like.

The reaction temperature of the grafting should be not lower than the melting point of the polyolefin and not higher than the decomposition temperature of the polyolefin, and also should be not lower than the one-hour half-life temperature of the radical generator. The reaction temperature is typically 100 to 200° C.

Preferred examples of radical generators used for the grafting include those that generate radicals at the reaction temperature in the grafting, and specifically include dibenzoyl peroxide, t-butyl peroxybenzoate, dicumylperoxide, methyl ethyl ketone peroxide, and azobisisobutyronitrile.

The amount of the radical generator is preferably not less than 10 parts by weight and less than 100 parts by weight relative to 100 parts by weight of the ethylenic unsaturated silane compound. If the amount of the radical generator is less than 10 parts by weight, the grafting reaction does not proceed sufficiently, possibly resulting in low adhesion of the solar cell encapsulant sheet to the solar cell element. If the amount of the radical generator is 100 parts by weight or more, generated radicals unfavorably accelerate the crosslinking reaction of the polyolefin, which may cause gelation in the process of forming the solar cell encapsulant sheet. Consequently, holes may be formed, and the solar cell encapsulant sheet may be torn.

The silane-modified polyolefin resin preferably has a viscoelastic storage modulus at 100° C. of not less than 1×10⁴ Pa and not more than 5×10⁶ Pa. If the viscoelastic storage modulus of the silane-modified polyolefin resin at 100° C. is less than 1×10⁴ Pa, the solar cell encapsulant sheet may significantly flow when pressing force is applied to encapsulate the solar cell element with the solar cell encapsulant sheet in the process of producing a solar cell module. In this case, the thickness of the solar cell encapsulant sheet may become significantly uneven. If the viscoelastic storage modulus of the silane-modified polyolefin resin at 100° C. is more than 5×10⁶ Pa, the adhesion of the solar cell encapsulant sheet to the solar cell element may be weak. The more preferable lower limit of the viscoelastic storage modulus of the silane-modified polyolefin resin at 100° C. is 1×10⁵ Pa, and the more preferable upper limit is 1×10⁶ Pa.

The viscoelastic storage modulus of the silane-modified polyolefin resin at 100° C. can be controlled by adjusting the amounts of the α-olefin and the modifying silane in the silane-modified polyolefin resin. A resin containing more α-olefin and/or less modifying silane has a lower viscoelastic storage modulus at 100° C., and a resin containing less α-olefin and/or more modifying silane has a higher viscoelastic storage modulus at 100° C.

The viscoelastic storage modulus at 30° C. of the silane-modified polyolefin resin is preferably not less than 1×10⁷ Pa and not more than 2×10⁸ Pa.

If the viscoelastic storage modulus at 30° C. of the silane-modified polyolefin resin is less than 1×10⁷ Pa, the solar cell encapsulant sheet may become sticky at room temperature, and therefore may be difficult to handle. If the viscoelastic storage modulus at 30° C. is more than 2×10⁸ Pa, the solar cell encapsulant sheet may be less flexible, and therefore may be difficult to handle. Additionally, rapid heating of the solar cell encapsulant sheet may be required to encapsulate the solar cell element with the solar cell encapsulant sheet in the process of producing a flexible solar cell module. The more preferable upper limit of the viscoelastic storage modulus at 100° C. of the silane-modified polyolefin resin is 1.5×10⁸ Pa.

The viscoelastic storage modulus of the silane-modified polyolefin resin is measured by a testing method for dynamic properties in accordance with JIS K6394.

The silane-modified polyolefin resin preferably has a maximum peak temperature (Tm) of 80 to 125° C. as determined from an endothermic curve obtained by differential scanning calorimetry.

If the maximum peak temperature (Tm) determined from an endothermic curve is lower than 80° C., the solar cell encapsulant sheet may be less heat resistant. If the maximum peak temperature (Tm) determined from an endothermic curve is higher than 125° C., the solar cell encapsulant sheet may require a longer period of heating in the encapsulation process, leading to lower production efficiency of flexible solar cell modules or failing to sufficiently encapsulate the solar cell.

The maximum peak temperature (Tm) of an endothermic curve is more preferably 85 to 120° C.

The maximum peak temperature (Tm) of an endothermic curve obtained by differential scanning calorimetry is measured in accordance with the method specified in JIS K7121.

The silane-modified polyolefin resin preferably has a melt flow rate (MFR) of 0.5 g/10 min to 29 g/10 min. If the melt flow rate is less than 0.5 g/10 min, uneven portions may be formed on the solar cell encapsulant sheet in the process of forming the encapsulant sheet, resulting in production of a flexible solar cell module that tends to curl. If the melt flow rate is more than 29 g/10 min, the possibility of drawdown in the process of forming the solar cell encapsulant sheet is high, in other words, it is difficult to form a sheet with an even thickness. This case may also result in production of a flexible solar cell module that tends to curl, or formation of pinholes or the like in the solar cell encapsulant sheet which may cause a resulting flexible solar cell module to entirely lose insulation properties.

The melt flow rate is more preferably 2 g/10 min to 10 g/10 min.

The melt flow rate of the silane-modified polyolefin resin is measured under a load of 2.16 kg in accordance with ASTM D1238, which is used to measure the melt flow rate of polyethylene resins.

The silane-modified polyolefin resin may be a commercial product. Examples of commercial products of the silane-modified polyolefin resin include LINKLON available from Mitsubishi Chemical Corp.

The silane-modified polyolefin resin may be a resin mixture of such a silane-modified polyolefin resin as described above and a non silane-modified polyolefin resin.

Examples of usable mixtures include a mixture prepared by combining a non silane-modified polyolefin resin with such a commercial silane-modified polyolefin resin product as described above such that the Tm, MFR and viscoelasticity storage modulus are adjusted to the above preferable ranges.

Preferred examples of non silane-modified polyolefin resins include ethylene-α-olefin copolymers. The same as those listed for the ethylene-α-olefin copolymer may be mentioned as examples of such ethylene-α-olefin copolymers.

Any methods for blending the resins can be used without limitation. Examples include a method in which silane-modified polyolefin resin pellets and non silane-modified polyolefin resin pellets are mixed in a mixer such as a tumbler, and the resulting mixture is transferred to a single or twin screw extruder and kneaded therein, and a method in which the silane-modified polyolefin resin is molten and kneaded in a kneader, a Bunbury mixer, or the like, and the non silane-modified polyolefin resin is added thereto and kneaded.

In the case of using a resin mixture of the silane-modified polyolefin resin and the non silane-modified polyolefin resin, the blending ratio (silane-modified polyolefin resin/non silane-modified polyolefin resin) is preferably 30/70 to 70/30 on a weight basis.

The adhesive layer may further contain other additives such as photostabilizers, ultraviolet absorbers, and heat stabilizers in amounts that do not impair the physical properties of the adhesive layer.

Examples of methods for forming the adhesive layer include a method involving melting a predetermined ratio (weight basis) of the silane-modified polyolefin resin and optionally predetermined ratios (weight basis) of additives in an extruder, kneading the mixture, and extruding the mixture into a sheet from the extruder.

The thickness of the adhesive layer is preferably 80 to 700 μm. If the thickness of the adhesive layer is less than 80 μm, the adhesive layer may fail to ensure the insulative properties of flexible solar cell modules. If the thickness of the adhesive layer is more than 700 μm, flexible solar cell modules with impaired flame retardancy or heavy flexible solar cell modules may be provided. Additionally, it is disadvantageous for cost reasons. The thickness of the adhesive layer is more preferably 150 to 400 μm.

In the solar cell encapsulant sheet, the adhesive layer is formed on a fluoropolymer sheet.

The fluoropolymer sheet is not particularly limited, provided that it is excellent in transparency, heat resistance, and flame retardancy. However, the fluoropolymer sheet preferably includes at least one fluoropolymer selected from the group consisting of tetrafluoroethylene-ethylene copolymers (ETFE), ethylene-chlorotrifluoroethylene resins (ECTFE), polychlorotrifluoroethylene resins (PCTFE), polyvinylidene fluoride resins (PVDF), tetrafluoroethylene-perfluoroalkyl vinyl ether copolymers (FAP), polyvinyl fluoride resins (PVF), tetrafluoroethylene-hexafluoropropylene copolymers (FEP), vinylidene fluoride-hexafluoropropylene copolymers (PVDF-HFP), and a mixture of polyvinylidene fluoride and polymethylmethacrylate (PVDF/PMMA).

In particular, the fluoropolymer is more preferably selected from polyvinylidene fluoride resins (PVDF), tetrafluoroethylene-ethylene copolymers (ETFE), and polyvinyl fluoride resins (PVF) because of their better heat resistance and transparency.

The thickness of the fluoropolymer sheet is preferably 10 to 100 μm. If the thickness of the fluoropolymer sheet is less than 10 μm, the fluoropolymer sheet may fail to ensure the insulative properties, and may impair the flame retardancy. If the thickness of the fluoropolymer sheet is more than 100 μm, heavy flexible solar cell modules may be provided, which is disadvantageous for cost reasons. The thickness of the fluoropolymer sheet is more preferably 15 to 80 μm.

The solar cell encapsulant sheet can be formed by integrating the fluoropolymer sheet and the adhesive layer into a laminate. The integration into a laminate can be accomplished by any methods, and examples of integration methods include a method in which the fluoropolymer sheet is formed on one surface of the adhesive layer by extrusion lamination, and a method in which the adhesive layer and the fluoropolymer sheet are formed by coextrusion. In particular, it is preferable to simultaneously form the sheet and the layer as a laminate by coextrusion.

The extrusion temperature in the coextrusion process is preferably higher than the melting point of the fluoropolymer and the silane-modified polyolefin resin by 30° C. or more and is preferably lower than the decomposition temperature thereof by 30° C. or more.

As described above, the solar cell encapsulant sheet is preferably an integrated laminate formed by simultaneously forming the adhesive layer and the fluoropolymer sheet by coextrusion.

The solar cell encapsulant sheet preferably has an embossed surface. In particular, a surface of the solar cell encapsulant sheet which is to be a light-receiving surface in use is preferably embossed. More specifically, a surface of the fluoropolymer sheet of the solar cell encapsulant sheet which is to be a light-receiving surface of a produced flexible solar cell module is preferably embossed.

The embossed pattern reduces the reflection loss of sunlight, prevents glare, and improves the appearance.

The embossed pattern may consist of peaks and valleys arranged in a regular pattern or peaks and valleys arranged in a random fashion.

The embossed pattern may be formed before or after adhering the solar cell encapsulant sheet to the solar cell element, or may be formed at the same time as adhering to a solar cell element.

Preferably, the embossed pattern is formed before adhering to the solar cell element in order to prevent the surface from being non-uniformly embossed and provide a uniformly embossed pattern.

In particular, the embossed pattern is more preferably formed by using an embossing roll as a chill roll in such a manner that the roll embosses the surface while cooling the molten resin in the process of simultaneously forming the adhesive layer and the fluoropolymer sheet of the solar cell encapsulant sheet by coextrusion because the embossed pattern does not deform and is uniformly preserved in the process of adhering to the solar cell element.

The solar cell element commonly includes a photoelectric conversion layer that generates electrons when receiving light, an electrode layer that draws generated electrons, and a flexible substrate.

The solar cell element may be made of, for example, a crystalline semiconductor (e.g. monocrystal silicon, monocrystal germanium, polycrystal silicon, microcrystal silicon), an amorphous semiconductor (e.g. amorphous silicon), a compound semiconductor (e.g. GaAs, InP, AlGaAs, Cds, CdTe, Cu₂S, CuInSe₂, CuInS₂), or an organic semiconductor (e.g. phthalocyanine, polyacetylene).

The solar cell element may be a monolayer or a multilayer.

The thickness of the solar cell element is preferably 0.5 to 10 μm.

The flexible substrate is not particularly limited, provided that it is flexible and suited for flexible solar cell modules. Examples thereof include substrates made of a heat resistant resin such as polyimide, polyether ether ketone, or polyethersulfone.

The thickness of the flexible substrate is preferably 10 to 80 μm.

The electrode layer is a layer made of an electrode material.

The electrode layer may be formed on the photoelectric conversion layer, between the photoelectric conversion layer and the flexible substrate, or on the flexible substrate, according to need.

For an electrode layer located on the light-receiving surface side (front surface), the electrode material is preferably a common transparent electrode material such as a metal oxide because it should be transparent. The transparent electrode material is not particularly limited, but ITO, ZnO, and the like are suitably used.

In the case that it is not a transparent electrode, it may be a metal (e.g. silver) patterned bus electrode or a metal (e.g. silver) patterned finger electrode, which is used with a bus electrode.

In the case that the electrode layer is located on the back side (back surface), it is not necessarily transparent and may be made of a common electrode material. The electrode material, however, is preferably silver.

The solar cell element is produced by any common methods, and examples thereof include a known method in which the photoelectric conversion layer and electrode layers are stacked on the flexible substrate.

The solar cell element may be a long sheet wound into a roll or a rectangular sheet.

The method for producing a flexible solar cell module of the present invention includes thermocompression bonding of the solar cell encapsulant sheet to at least the light-receiving surface of the solar cell element by pressing the solar cell encapsulant sheet and the solar cell element between a pair of heating rolls.

The light-receiving surface of the solar cell element is a surface that receives light, and refers to the photoelectric conversion layer-side surface and not to the flexible substrate-side surface.

The temperature of the heating rolls used in the pressing process is preferably 80 to 160° C. If the heating roll temperature is lower than 80° C., adhesion failure may occur. If the heating roll temperature is higher than 160° C., wrinkles are likely to occur by the thermocompression bonding. The more preferable heating roll temperature is 90 to 120° C.

The rotation speed of the heating rolls is preferably 0.1 to 10 m/min. If the rotation speed of the heating rolls is less than 0.1 m/min, wrinkles are likely to occur after the thermocompression bonding. If the rotation speed of the heating rolls is more than 10 m/min, adhesion failure may occur. The rotation speed of the heating rolls is more preferably 0.3 to 5 m/min.

Because of the presence of the above-described specific resin in the adhesive layer of the solar cell encapsulant sheet, the method for producing a flexible solar cell module of the present invention allows any crosslinking processes to be omitted, and therefore allows short-term thermocompression bonding. Additionally, the thermocompression bonding can be carried out at low temperatures. Therefore, the method can prevent wrinkles and curls while ensuring sufficient adhesion between the solar cell element and the solar cell encapsulant sheet. Consequently, flexible solar cell modules can be efficiently produced by roll-to-roll processing.

The following description is offered to specifically illustrate the method for producing a flexible solar cell module of the present invention using FIG. 1.

As shown in FIG. 1, a solar cell element A and a solar cell encapsulant sheet B are both long sheets wound into a roll. First, the solar cell element A and the solar cell encapsulant sheet B are unrolled such that the light-receiving surface of the photoelectric conversion layer of the solar cell element A faces the adhesive layer surface of the solar cell encapsulant sheet B, and stacked to form a laminate sheet C.

Subsequently, the laminate sheet C is inserted between a pair of rolls D that are heated to a predetermined temperature, and the solar cell element A and the solar cell encapsulant sheet B are adhered to and integrated with each other by thermocompression bonding in which the laminate sheet C is heated and pressed in the thickness direction. Consequently, the solar cell element is encapsulated with the solar cell encapsulant sheet, thereby providing a flexible solar cell module E.

FIG. 2 is a vertical cross-sectional view schematically showing an exemplary solar cell element A used in the method for producing a flexible solar cell module of the present invention, and FIG. 3 is a vertical cross-sectional view schematically showing an exemplary solar cell encapsulant sheet B used in the method for producing a flexible solar cell module of the present invention. As shown in FIGS. 2 and 3, the solar cell element A includes a photoelectric conversion layer 2 on a flexible substrate 1. The solar cell encapsulant sheet B includes an adhesive layer 3 on a fluoropolymer sheet 4.

FIG. 4 is a vertical cross-sectional view schematically showing an exemplary flexible solar cell module produced by the production method of the present invention.

The photoelectric conversion layer 2-side surface of the solar cell element A is encapsulated with the adhesive layer 3, as shown in FIG. 4, so that the flexible solar cell module E, an integrated laminate of the solar cell element A and the solar cell encapsulant sheet B, is obtained.

The method for producing a flexible solar cell module of the present invention may further include thermocompression bonding of the solar cell encapsulant sheet to the flexible substrate-side surface (back surface) of the solar cell element by pressing the solar cell encapsulant sheet and the solar cell element between the heating rolls.

In the case that the flexible substrate-side surface of the solar cell element is encapsulated, a solar cell encapsulant sheet including such an adhesive layer as described above and an opaque stainless steel layer and the like may be used because light transmitting properties are not required.

The thermocompression bonding process of the solar cell encapsulant sheet to the surface of the flexible substrate of the solar cell element may be carried out before, after, or at the same time as the thermocompression bonding of the solar cell encapsulant sheet to the light-receiving surface of the solar cell element.

When the flexible substrate of the solar cell element is also adhered to the solar cell encapsulant sheet by thermocompression, the solar cell element is encapsulated more favorably. In this case, the resulting flexible solar cell module can stably generate electric power for a longer time.

The following description is offered to illustrate, using FIG. 5, one example of the method for producing a flexible solar cell module of the present invention in which the photoelectric conversion layer (front surface) and the flexible substrate (back surface) of a solar cell element are simultaneously encapsulated.

Specifically, in addition to a long solar cell element wound into a roll, two long solar cell encapsulant sheets wound into rolls are prepared. As shown in FIG. 5, the long solar cell encapsulant sheets B and B are unrolled while the long solar cell element A is also unrolled. The solar cell encapsulant sheets B and B are set such that the adhesive layers of the two sheets face each other, and stacked with the solar cell element A sandwiched therebetween to form a laminate sheet C. The laminate sheet C is inserted between a pair of rolls D and D that are heated to a predetermined temperature, and the solar cell encapsulant sheets B and B are adhered to and integrated with each other by heating and pressing the laminate sheet C in the thickness direction so that the solar cell element A is encapsulated between the solar cell encapsulant sheets B and B. In this manner, a flexible solar cell module F is formed in a continuous manner.

In the method for producing a flexible solar cell module, the pressing of the laminate sheet C in the thickness direction under heating may be performed at the same time as the formation of the laminate sheet C by stacking the solar cell encapsulant sheets B and B with the solar cell element A sandwiched therebetween.

FIG. 6 shows one example of production of a flexible solar cell module in the case of using a rectangular solar cell element A.

Specifically, rectangular sheets of a solar cell element A with a predetermined size are prepared instead of the long solar cell element wound into a roll. As shown in FIG. 6, the long solar cell encapsulant sheets B and B are unrolled such that the adhesive layers of these sheets face each other, and the solar cell elements A are delivered between the solar cell encapsulant sheets B and B at regular time intervals. Thus, the solar cell encapsulant sheets B and B are stacked with the solar cell elements A sandwiched therebetween to form a laminate sheet C. The laminate sheet C is inserted between a pair of rolls D and D that are heated to a predetermined temperature, and the solar cell encapsulant sheets B and B are adhered to and integrated with each other by heating and pressing the laminate sheet C in the thickness direction so that the solar cell elements A are encapsulated between the solar cell encapsulant sheets B and B. In this manner, flexible solar cell modules F are formed in a continuous manner.

In the method for producing a flexible solar cell module, the pressing of the laminate sheet C in the thickness direction under heating may be performed at the same time as the formation of the laminate sheet C.

FIG. 7 is a vertical cross-sectional view schematically showing an example of flexible solar cell modules produced by encapsulating the photoelectric conversion layer (front surface) and the flexible substrate (back surface) of the solar cell element.

As described above, the method for producing a flexible solar cell module of the present invention is characterized by encapsulating a solar cell element with a solar cell encapsulant sheet having specific features.

The method can suitably produce flexible solar cell modules in which a solar cell element and a solar cell encapsulant sheet are well adhered to each other by roll-to-roll processing without causing wrinkles and curls.

### Advantageous Effects of Invention

Because of the features described above, the method for producing a flexible solar cell module of the present invention makes it possible to suitably produce flexible solar cell modules in which a solar cell element and a solar cell encapsulant sheet are well adhered to each other by encapsulating a solar cell element by roll-to-roll processing in a continuous manner without the need to perform a crosslinking process and without causing wrinkles and curls.

### BRIEF DESCRIPTION OF DRAWINGS

FIG. 1 is a schematic view showing one example of production by the method for producing a flexible solar cell module of the present invention;

FIG. 2 is a vertical cross-sectional view schematically showing an exemplary solar cell element used in the method for producing a flexible solar cell module of the present invention;

FIG. 3 is a vertical cross-sectional view showing an exemplary solar cell encapsulant sheet used in the method for producing a flexible solar cell module of the present invention;

FIG. 4 is a vertical cross-sectional view showing an exemplary flexible solar cell module produced by the method for producing a flexible solar cell module of the present invention;

FIG. 5 is a schematic view showing one example of production by the method for producing a flexible solar cell module of the present invention;

FIG. 6 is a schematic view showing one example of production by the method for producing a flexible solar cell module of the present invention;

FIG. 7 is a vertical cross-sectional view showing an exemplary flexible solar cell module produced by the method for producing a flexible solar cell module of the present invention; and

FIG. 8 is a schematic view showing one example of production by the method for producing a flexible solar cell module of a comparative example.

### DESCRIPTION OF EMBODIMENTS

The following examples are offered to illustrate the present invention in more detail, but are not to be construed as limiting the present invention.

### Examples 1 to 3

A silane-modified polyolefin resin (A) (100 parts by weight) having a predetermined α-olefin content shown in Table 1 was molten and kneaded in a first extruder at 230° C. Separately, a fluoropolymer shown in Table 1 was molten and kneaded in a second extruder at 230° C. The molten silane-modified polyolefin resin (A) and fluoropolymer were supplied to a coalescent die connecting the first extruder and the second extruder where the resins were contacted, and then the resins were extruded from a T die connected to the coalescent die into a sheet. In this manner, a long solar cell encapsulant sheet of a predetermined width was obtained as an integrated laminate which consisted of a 0.3 mm-thick adhesive layer and a 0.03 mm-thick fluoropolymer sheet.

Table 1 shows the modifying silane amounts, the melt flow rates (MFR), the maximum peak temperatures (Tm) determined from endothermic curves obtained by differential scanning calorimetry analysis, and the viscoelastic storage moduli at 30° C. and 100° C. of the silane-modified polyolefin resins (A).

Subsequently, the solar cell encapsulant sheets obtained above were used to produce flexible solar cell modules in the manner described below.

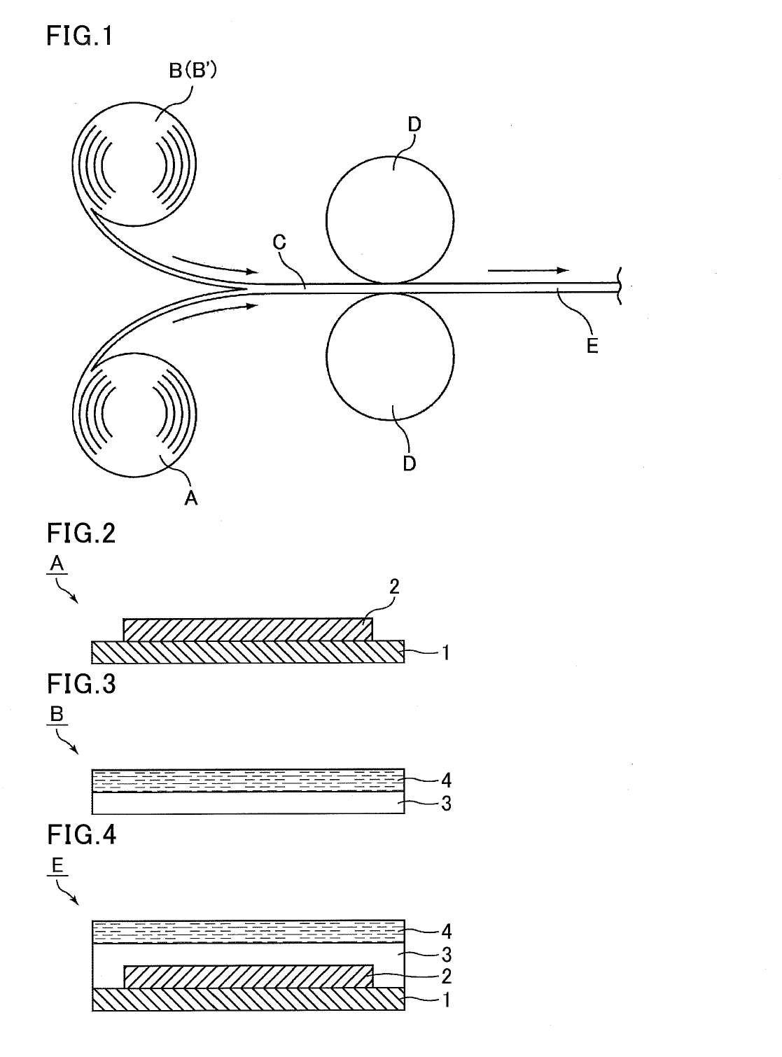

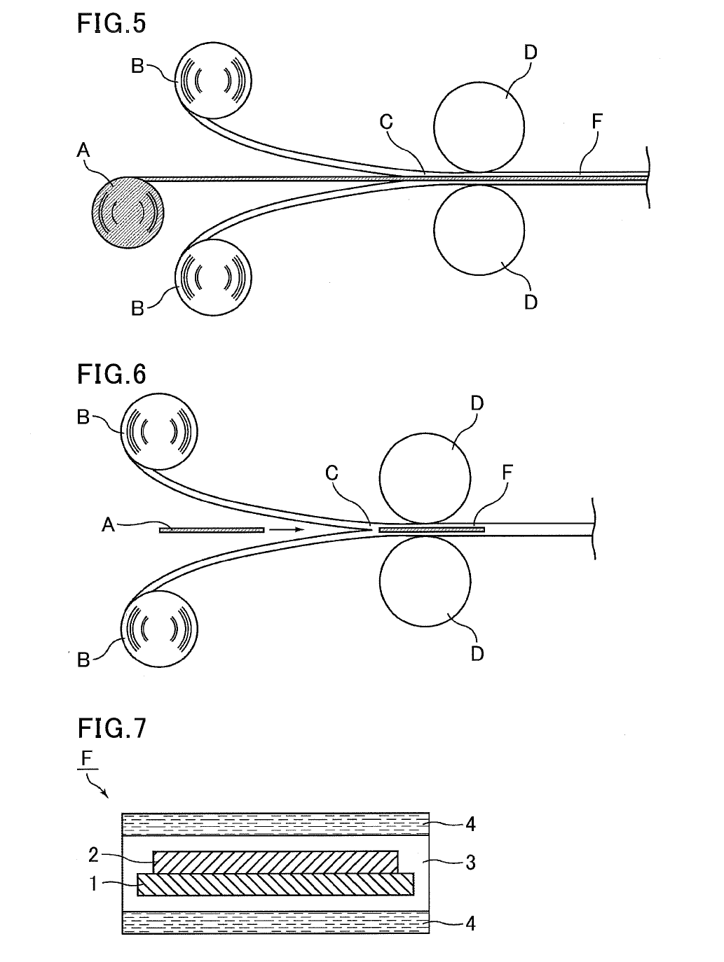

First, as shown in FIG. 1, a roll of a sheet that consisted of a flexible substrate made of a flexible polyimide film and a photoelectric conversion layer made of an amorphous silicon thin film on the flexible substrate was prepared as a solar cell A, and a roll of a solar cell encapsulant sheet obtained above were prepared as a solar cell encapsulant sheet B′.

Next, as shown in FIG. 1, the solar cell element A and the solar cell encapsulant sheet B′ were unrolled. The solar cell encapsulant sheet B′ was stacked on the photoelectric conversion layer of the solar cell element A such that the adhesive layer faced the photoelectric conversion layer. In this manner, a laminate sheet C was obtained. The laminate sheet C was delivered between a pair of rolls D and D heated to a temperature shown in Table 1 at a speed shown in Table 1, and pressed in the thickness direction under heating so that the solar cell encapsulant sheet B′ was adhered to and integrated with the solar cell element A. In this manner, the solar cell element was encapsulated, and a flexible solar cell module E was produced in a continuous manner. The flexible solar cell module E was wound along a winder (not shown).

### Examples 4 and 5

A flexible solar cell module was formed in the same manner as in Example 1, except that 100 parts by weight of a resin mixture of predetermined ratios of a predetermined silane-modified polyolefin resin (A) and a polyolefin resin (B) shown in Table 1 was used instead of using 100 parts by weight of the silane-modified polyolefin resin (A). Table 1 shows the MFR, Tm, and viscoelastic storage moduli at 30° C. and 100° C. of the resin mixtures.

### Comparative Example 1

A flexible solar cell module was formed in the same manner as in Example 1, except that an EVA resin was used instead of using the silane-modified polyolefin resin (A).

### Comparative Example 2

The silane-modified polyolefin resin (A) and the polyvinylidene fluoride used in Example 1 were separately extruded into a 0.3 mm-thick adhesive sheet and a 0.03 mm-thick polyvinylidene fluoride sheet, respectively.

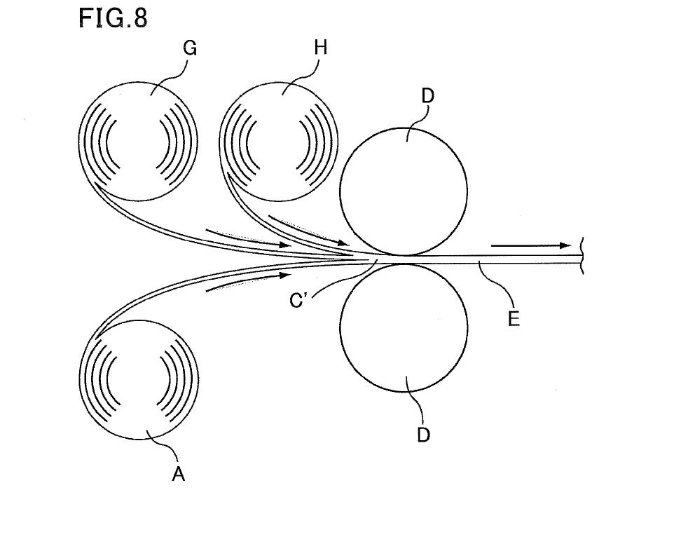

Next, as shown in FIG. 8, the solar cell element A, the adhesive sheet G, and the polyvinylidene fluoride sheet H were unrolled, and these three sheets were stacked into a laminate sheet C′. The laminate sheet C′ was delivered between a pair of rolls D and D heated to a temperature shown in Table 1 at a speed shown in Table 1, and pressed in the thickness direction under heating so that the solar cell element A, the adhesive sheet G, and the polyvinylidene fluoride sheet H were adhered to and integrated with one another. In this manner, the solar cell element was encapsulated, and a flexible solar cell module E was produced in a continuous manner. The flexible solar cell module E was wound along a winder (not shown).

### EVALUATION

The flexible solar cell modules thus obtained were analyzed for occurrence of wrinkles and curls, peeling strength, and resistance to high-temperature, high-humidity conditions in the following manner. Table 1 shows the results.

### <Occurrence of Wrinkles>

The flexible solar cell modules obtained above were visually evaluated for occurrence of wrinkles and scored based on the following criteria. The ratings of 4 or higher are regarded as being acceptable.

5: No wrinkles were observed.
4: The number of 0.5-mm or shorter winkles observed per unit length (m) was 1.
3: The number of 0.5-mm or shorter winkles observed per unit length (m) was 2 to 4.
2: The number of 0.5-mm or shorter winkles observed per unit length (m) was 5 or more.
1: Large wrinkles with a length of 0.5 mm or more were observed.

### <Occurrence of Curls>

A 500 mm×500 mm piece of each flexible solar cell module was placed on a flat surface, and measured for the height of an edge part curling up from the flat surface.

⊚ (Double circle): less than 20 mm

∘ (Circle): 20 mm or more and less than 25 mm

Δ (Triangle): 25 mm or more and less than 35 mm
x (Cross): 35 mm or more

### <Peeling Strength>

Each flexible solar cell module obtained above was measured for the peeling strength by peeling the solar cell encapsulant sheet from the flexible substrate of the solar cell element in accordance with JIS K6854.

### <Resistance to High-Temperature, High-Humidity Conditions>

Each flexible solar cell module obtained above was left at 85° C. and a relative humidity of 85%, and measured for the time from when the solar cell module was allowed to stand in this environment to when the solar cell encapsulant sheet began to come off from the flexible substrate of the solar cell element.

TABLE 1

| | | | | | | | Comparative | Comparative |
|---|---|---|---|---|---|---|---|---|
| | | Example 1 | Example 2 | Example 3 | Example 4 | Example 5 | Example 1 | Example 2 |
| Fluoropolymer | | PVDF | PVDF | ETFE | PVDF | PVDF | PVDF | PVDF |
| Adhesive | Silane-modified polyolefin | Silane- | Silane- | Silane- | Silane- | Silane- | EVA | Silane-modified |
| layer | resin (A) | modified | modified | modified | modified | modified | | ethylene-butene |
| | | ethylene- | ethylene- | ethylene- | ethylene- | ethylene- | | copolymer |
| | | butene | butene | hexene | butene | hexene | | |
| | | copolymer | copolymer | copolymer | copolymer | copolymer | | |
| | α-Olefin content | Butene | Butene | Hexene | Butene | Hexene | Vinyl acetate | Butene |
| | (% by weight) | (10%) | (20%) | (25%) | (20%) | (25%) | (25%) | (10%) |
| | Amount of modifying silane | 0.2 | 9 | 5 | 9 | 8 | 0 | 0.2 |
| | (parts by weight) | | | | | | | |
| | Polyolefin resin (B) | — | — | — | Ethylene- | Ethylene- | — | — |
| | | | | | butene | hexene | | |
| | | | | | copolymer | copolymer | | |
| | α-Olefin content | — | — | — | Butene | Hexene | — | — |
| | (% by weight) | | | | (10%) | (25%) | | |
| | A/B (weight ratio) | 100/0 | 100/0 | 100/0 | 50/50 | 40/60 | 100/0 | 100/0 |
| | MFR (g/10 min) | 7 | 3 | 2 | 5 | 4 | 5 | 7 |
| | Tm (° C.) | 95 | 89 | 100 | 92 | 100 | 75 | 95 |
| | Viscoelastic storage modulus | 9 × 10⁷ | 1 × 10⁸ | 1.5 × 10⁸ | 1 × 10⁸ | 1.5 × 10⁸ | 2 × 10⁸ | 9 × 10⁷ |
| | at 30° C. | | | | | | | |
| | Viscoelastic storage modulus | 1 × 10⁵ | 4 × 10⁵ | 1 × 10⁵ | 2 × 10⁵ | 7 × 10⁵ | 0 | 1 × 10⁵ |
| | at 100° C. | | | | | | | |

| | | | | | | | |
|---|---|---|---|---|---|---|---|
| Lamination of fluoropolymer layer and | Integrated | Integrated | Integrated | Integrated | Integrated | Integrated | Separated layers |
| adhesive layer | | | | | | | |
| Roll temperature (° C.) | 150 | 150 | 150 | 150 | 150 | 120 | 150 |
| Rotation speed (m/min) | 2 | 5 | 1 | 5 | 2 | 2 | 2 |
| Wrinkles | 5 | 5 | 5 | 5 | 5 | 2 | 1 |
| Curls | ⊚ | ⊚ | ⊚ | ⊚ | ⊚ | ◯ | Δ |
| Peeling strength | 65 N/cm | 70 N/cm | 82 N/cm | 65 N/cm | 65 N/cm | 60 N/cm | 40 N/cm |
| Resistance to high temperature | 5000 hours | 5000 hours | 5000 hours | 5000 hours | 5000 hours | 10 hours | 1000 hours |
| and high humidity | or longer | or longer | or longer | or longer | or longer | | |

### INDUSTRIAL APPLICABILITY

The method for producing a flexible solar cell module of the present invention makes it possible to suitably produce flexible solar cell modules in which a solar cell element and a solar cell encapsulant sheet are well adhered to each other by roll-to-roll processing without causing wrinkles and curls.

### REFERENCE SIGNS LIST

A Solar cell element
B, B′ Solar cell encapsulant sheet
C, C′ Laminate sheet
D Roll
E, F Flexible solar cell module
G Adhesive sheet
H Polyvinylidene fluoride sheet
1 Flexible substrate
2 Photoelectric conversion layer
3 Adhesive layer
4 Fluoropolymer sheet

1. A method for producing a flexible solar cell module, comprising thermocompression bonding of a solar cell encapsulant sheet to at least a light-receiving surface of a solar cell element that comprises a flexible substrate and a photoelectric conversion layer on the flexible substrate by pressing the solar cell encapsulant sheet and the solar cell element together between a pair of heating rolls,
the solar cell encapsulant sheet comprising a fluoropolymer sheet and an adhesive layer on the fluoropolymer sheet, the adhesive layer comprising a silane-modified polyolefin resin.

2. The method for producing a flexible solar cell module according to claim 1,
wherein the fluoropolymer sheet comprises at least one fluoropolymer selected from the group consisting of tetrafluoroethylene-ethylene copolymers, ethylene-chlorotrifluoroethylene resins, polychlorotrifluoroethylene resins, polyvinylidene fluoride resins, tetrafluoroethylene-perfluoroalkyl vinyl ether copolymers, polyvinyl fluoride resins, tetrafluoroethylene-hexafluoropropylene copolymers, vinylidene fluoride-hexafluoropropylene copolymers, and a mixture of polyvinylidene fluoride and polymethylmethacrylate.

3. The method for producing a flexible solar cell module according to claim 1,
wherein the silane-modified polyolefin resin has a viscoelastic storage modulus at 100° C., as determined by a testing method for dynamic properties in accordance with JIS K6394, of not less than 1×10⁴ Pa and not more than 5×10⁶ Pa.

4. The method for producing a flexible solar cell module according to claim 1,
wherein the solar cell encapsulant sheet is an integrated laminate of the fluoropolymer sheet and the adhesive layer that are simultaneously formed and stacked by coextrusion.

5. The method for producing a flexible solar cell module according to claim 2,
wherein the solar cell encapsulant sheet is an integrated laminate of the fluoropolymer sheet and the adhesive layer that are simultaneously formed and stacked by coextrusion.

6. The method for producing a flexible solar cell module according to claim 3,
wherein the solar cell encapsulant sheet is an integrated laminate of the fluoropolymer sheet and the adhesive layer that are simultaneously formed and stacked by coextrusion.
